(19) United States
(12) Patent Application Publication
(10) Pub. No.: US 2014/0347068 A1
(43) Pub. Date: Nov. 27, 2014

(54) SIGNAL INTEGRITY TEST SYSTEM AND METHOD

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: XIAO-LONG ZHOU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/185,167

(22) Filed: Feb. 20, 2014

(30) Foreign Application Priority Data
May 27, 2013 (CN) 2013102004657

(51) Int. Cl. G01R 31/02

(52) U.S. Cl. CPC G01R 31/02
USPC 324/539

(57) ABSTRACT

A signal integrity test system includes a signal generator, a CPLD, and an indicating light. The signal generator is electrically connected to an input end of transmission lines to generate a simulation signal having a waveform simulating a waveform from a signal source. The CPLD includes a switching module, a sampling module, and a judging module. The switching module generates a sampling clock corresponding to the waveform of the simulation signal. The sampling module is electrically connected to the switching module and samples the simulation signal by the sampling clock, and then transmits a sampling result to the judging module. The judging module compares the sampling result with a standard waveform and displays a comparison result through the indicating light. The disclosure further provides a signal integrity test method.

### FIELD

Embodiments of the present disclosure relate to signal test systems and methods, and particularly to a signal integrity test system and method.

### BACKGROUND

In a server system and an interchanger system, transmission lines are capable of transmitting signals between a transmitter, such as a central processing unit (CPU), and a receiver, such as a Complex Programmable Logic Device (CPLD). To ensure stability of the system, the signals must be uniform. However, the signals are tested manually, which is inaccurate and time-consuming.

### BRIEF DESCRIPTION OF THE DRAWINGS

FIG. 1 is a block diagram of one embodiment of function modules of a signal integrity test system.

FIG. 2 is a flowchart of one embodiment of a signal integrity test method.

### DETAILED DESCRIPTION

The disclosure is illustrated by way of examples and not by way of limitation in the figures of the accompanying drawings in which like references indicate similar elements. It should be noted that references to “an” or “one” embodiment in this disclosure are not necessarily to the same embodiment, and such references mean “at least one.”

In general, the word “module,” as used hereinafter, refers to logic embodied in hardware or firmware, or to a collection of software instructions, written in a programming language, such as, for example, Java, C, or Assembly. One or more software instructions in the modules can be embedded in firmware. Modules can comprise connected logic units, such as gates and flip-flops, and programmable units, such as programmable gate arrays or processors. The modules described herein can be implemented as either software and/or hardware modules and can be stored in any type of computer-readable medium or computer storage device.

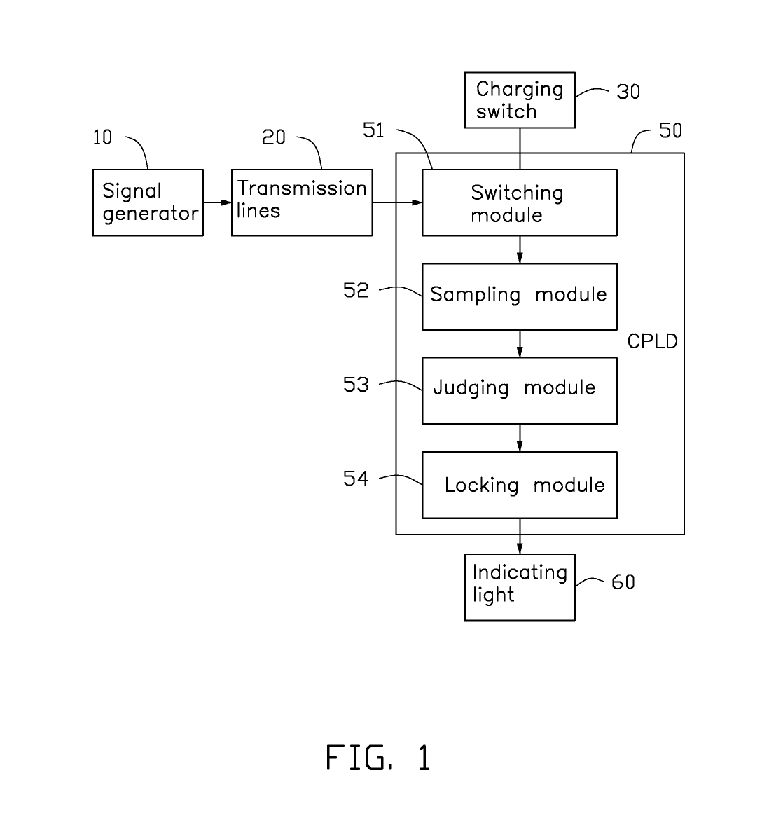

FIG. 1 shows one embodiment of a signal integrity test system. The signal integrity test system includes a signal generator 10, transmission lines 20, a charging switch 30, a Complex Programmable Logic Device (CPLD 50), and an indicating light 60.

The signal generator 10 is electrically connected to an input end of the transmission lines 20 and generates simulation signals having waveforms simulating waveforms of signals generated by electronic components.

An output end of the transmission lines 20 is electrically connected to the CPLD 50. The simulation signals are transferred to the input end of the CPLD 50 via the transmission lines 20.

The CPLD 50 includes a switching module 51, a sampling module 52, a judging module 53, and a locking module 54.

The switching module 51 is electrically connected to the charging switch 30 and the input end of the transmission lines 20. The charging switch 30 switches sampling clock signals according to the waveform of the simulation signals.

The switching module 51 switches to a corresponding sampling clock according to the sampling clock signal.

The sampling module 52 is electrically connected to the output end of the switching module 51 and samples the simulation signals using the sampling clock, and then transfers a sampling result to the judging module 53.

The judging module 53 is electrically connected to the output end of the sampling module 52 and compares the sampling result with a standard waveform saved in the judging module 53, and then displays a comparison result through the indicating light 60.

The locking module 54 is electrically connected between the indicating light 60 and the judging module 53. The indicating light 60 lights up when the judging result fails, and does not light up when the judging result passes. The locking module 54 locks the judging module 53 after the judging module 53 transmits the judging result, thus keeping the indicating light 60 lit up or turned off.

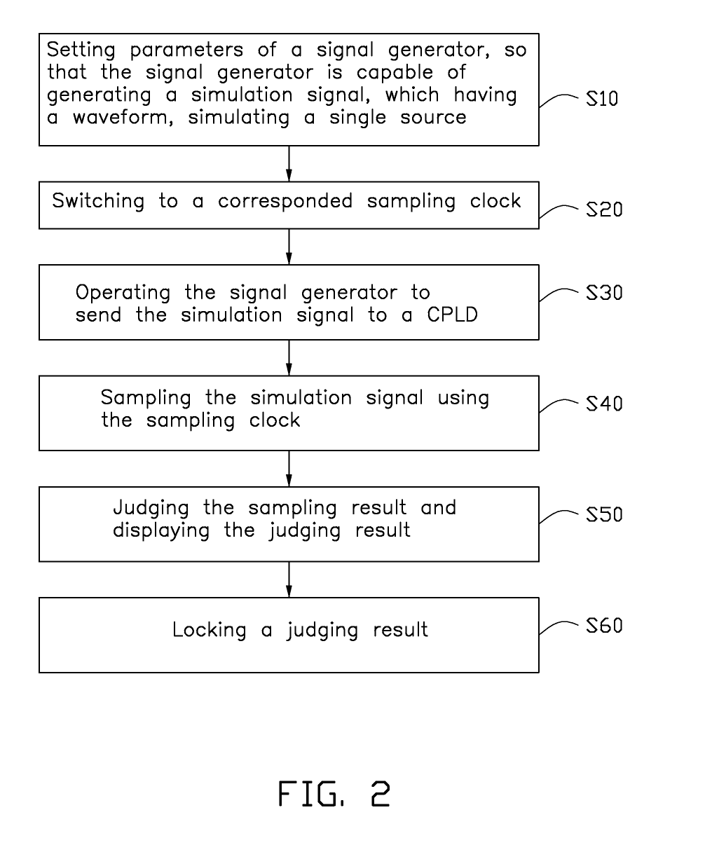

FIG. 2 is a flowchart of one embodiment of a signal integrity test method using the signal integrity test system in FIG. 1. Depending on the embodiment, additional steps may be added, others removed, and the ordering of the steps may be changed.

In step S10, parameters of the signal generator 10 are set, such that the signal generator 10 can generate a simulation signal having a waveform simulating a waveform of signals generated by the electronic components.

In step S20, the charging switch 30 switches the sampling clock signal according to the waveform of the simulation signal, and then the switching module 51 switches to the corresponding sampling clock according to the sampling clock signal.

In step S30, the signal generator 10 is operated to send the simulation signal to the CPLD 50 through the transmission lines 20.

In step S40, the sampling module 52 samples the simulation signal using the sampling clock, and then transfers the sampling result waveform to the judging module 53.

In step S50, the judging module 53 compares the sampling result waveform to the standard waveform saved in the judging module 53, and then displays a comparing result through the indicating light 60. The indicating light 60 lights up when the judging result fails, and does not light up when the judging result passes.

In step S60, the locking module 54 locks the judging module 53 after the judging module 53 transmits the judging result, thus keeping the indicating light 60 lit up or turned off.

Although certain inventive embodiments of the present disclosure have been specifically described, the present disclosure is not to be construed as being limited thereto. Various changes or modifications may be made to the present disclosure without departing from the scope and spirit of the present disclosure.

What is claimed is:

1. A signal integrity test system, comprising:
a plurality of transmission lines;
a signal generator connected to an input end of the transmission lines and configured to generate a simulation signal simulating a single source, and the simulation signal having a waveform;
an indicating light; and
a Complex Programmable Logic Device (CPLD) comprising:
a switching module configured for generating a sampling clock corresponding to the waveform of the simulation signal;
a sampling module connected to the switching module and configured for sampling the simulation signal using the sampling clock; and
a judging module connected to the indicating light and configured for receiving a sampling result sent from the sampling module and comparing the sampling result with a standard waveform and displaying a judging result through the indicating light.

2. The system of claim 1, further comprising a charging switch connected to the switching module, wherein the charging switch is configured for switching a sampling clock signal according to the waveform of the simulation signal; and the switching module is configured for switching to the sampling clock according to the sampling clock signal.

3. The system of claim 1, wherein the CPLD further comprises a locking module configured for locking a displaying state of the indicating light.

4. The system of claim 3, wherein the locking module is connected between the judging module and the indicating light.

5. The system of claim 3, wherein the locking module is configured for stopping the judging module from comparing after receiving the judging result.

6. A signal integrity test system, comprising:
a plurality of transmission lines;
a signal generator connected to an input end of the transmission lines and configured to generate a simulation signal simulating a single source, and the simulation signal having a waveform;
a charging switch configured for switching a sampling clock signal according to the simulation signal;
an indicating light; and
a CPLD comprising:
a switching module connected to the charging switch and configured for switching to a sampling clock according to the sampling clock signal;
a sampling module connected to the switching module and configured for sampling the simulation signal by the sampling clock; and
a judging module connected to the indicating light and configured for receiving a sampling result sent from the sampling module and comparing the sampling result with a standard waveform and displaying a judging result through the indicating light.

7. The system of claim 6, wherein the CPLD further comprises a locking module configured for locking a displaying state of the indicating light.

8. The system of claim 7, wherein the locking module is connected between the judging module and the indicating light.

9. The system of claim 7, wherein the locking module is configured for stopping the judging module from comparing after receiving the judging result.

10. A signal integrity test method, comprising:
(a) setting parameters of a signal generator, so that the signal generator is capable of generate a simulation signal, which having a waveform, simulating a single source;
(b) switch to a corresponded sampling clock;
(c) operating the signal generator to send the simulation signal to a CPLD;
(d) sampling the simulation signal using the sampling clock;
(e) judging a sampling result by comparing the sampling result with a standard waveform; and
(f) displaying a judging result.

11. The method of claim 10, further comprising locking the judging result after judging a sampling result is pass or fail in step (e).

12. The method of claim 11, further comprising locking the sampling result after sampling the simulation signal using the sampling clock in step (d).

13. The method of claim 10, wherein the step (b) comprising:
switching a sampling clock signal according to the waveform of the simulation signal; and
switching to a sampling clock according to the sampling clock signal.
